(19) United States
(12) Patent Application Publication
(10) Pub. No.: US 2011/0247669 A1
(43) Pub. Date: Oct. 13, 2011

(54) POWER-GENERATING DEVICE AND METHOD OF MAKING

(75) Inventor: David Peter Gerrard, Magnolia, TX (US)

(73) Assignee: Baker Hughes Incorporated, Houston, TX (US)

(21) Appl. No.: 12/756,222

(22) Filed: Apr. 8, 2010

(51) Int. Cl. H01L 35/30; B32B 37/24

(52) U.S. Cl. 136/205; 156/242; 156/244.11

(57) ABSTRACT

A power-generating device includes a thermoelectric material contoured to conform to at least a portion of a tubular and at least two conductors in operable communication with the thermoelectric material.

### BACKGROUND

Tubular systems often employ tools that require electrical power, such as, motors and solenoids, for example, in the case of a downhole completion application. Some systems employ dynamos to supply the electrical power needed. Dynamos are electrical generators that have rotors turned by mud motors or turbines driven by fluid flow. These devices serve their function adequately. However, with the moving parts operating within extreme environments, such as those found downhole including high pressures, high temperatures, fast moving erosive and caustic fluids littered with contaminants, for example, maintenance of such devices can be difficult, time consuming and labor intensive. Devices that lessen some of the foregoing issues are well received in the art.

### BRIEF DESCRIPTION

Disclosed herein is a power-generating device that includes a thermoelectric material contoured to conform to at least a portion of a tubular and at least two conductors in operable communication with the thermoelectric material.

Further disclosed is a method of making a generating device. The method includes, casting a sheet of thermoelectric material, bonding a layer of conductive material to a first surface of the thermoelectric material, and bonding a layer of conductive material to a second surface of the thermoelectric material thereby constructing a layered assembly. The layered assembly is formed to be perimetrically mountable to a tubular surface.

Further disclosed is a method of making a generating device. The method includes extruding a thermoelectric material, bonding a layer of conductive material to a first surface of the thermoelectric material, and bonding a layer of conductive material to a second surface of the thermoelectric material. The foregoing layered assembly is formed to be perimetrically mountable to a tubular surface.

### BRIEF DESCRIPTION OF THE DRAWINGS

The following descriptions should not be considered limiting in any way. With reference to the accompanying drawings, like elements are numbered alike:

FIG. 1 depicts an end view of a power-generating device disclosed herein;

FIG. 2 depicts a cross sectioned side view of the power-generating device of FIG. 1 taken at arrows 2-2;

FIG. 3 depicts a partially sectioned perspective view of a portion of a layered assembly employed in the construction of the power-generating device of FIG. 1;

FIG. 4 depicts a sequential representation of steps employed during an embodiment of a construction process for the power-generating device of FIG. 1; and

FIG. 5 depicts a partial side view of a downhole completion application employing the power-generating device of FIG. 1.

### DETAILED DESCRIPTION

A detailed description of one or more embodiments of the disclosed apparatus and method are presented herein by way of exemplification and not limitation with reference to the Figures.

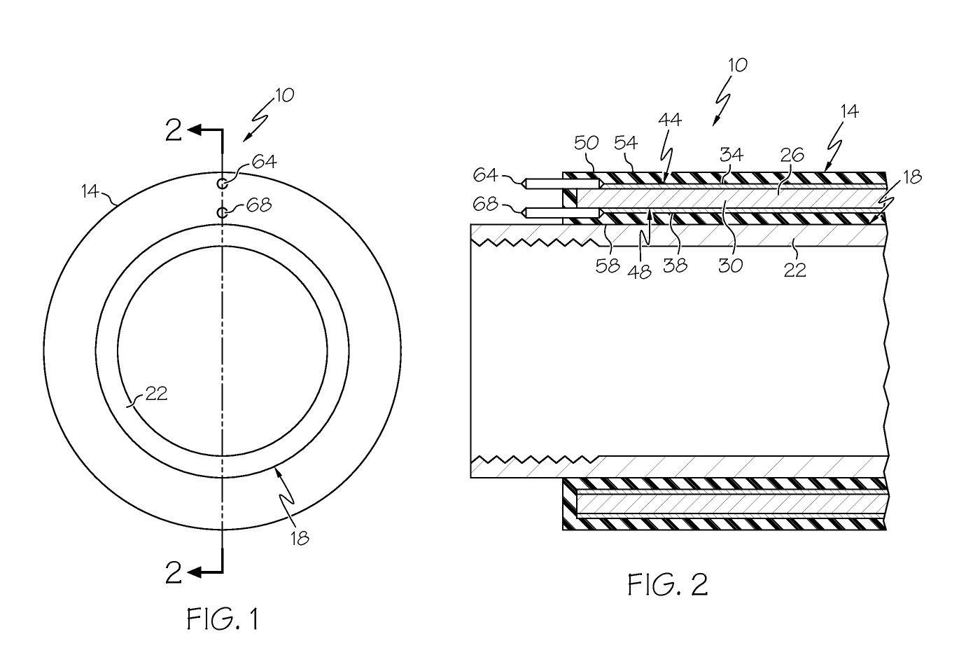

Referring to FIGS. 1-3, an embodiment of a power-generating device is disclosed generally at 10. The power-generating device 10 works on the principle of the Seebeck effect to convert temperature differences across a thermoelectric material directly into electricity, and uses no moving parts in the process. The power-generating device 10 includes, a layered assembly 14, conformed to a surface 18 (an outer surface in this embodiment) of a tubular 22. The layered assembly 14 has a core 26 of thermoelectric material 30, with conductors 34, 38, shown herein as layers of conductive material, electrically bonded to opposing surfaces 44, 48 of the thermoelectric material 30. A protector 50 including layers 54, 58 of electrically insulative material electrically insulates the conductors 34, 38 while fluidically isolating the conductors 34, 38 and the thermoelectric material 30 from an environment that the power-generating device 10 is submerged within. Terminals 64, 68 sealably penetrate the protector 50 and are electrically connected to the conductors 34, 38 respectively. The foregoing structure generates electrical energy in the thermoelectric material 30 when a radially oriented temperature gradient exists thereacross. Connection to the terminals 64, 68 allow the electrical energy generated to be conducted to a load (not shown) such as, an electrical motor, solenoid, heater or battery, for example.

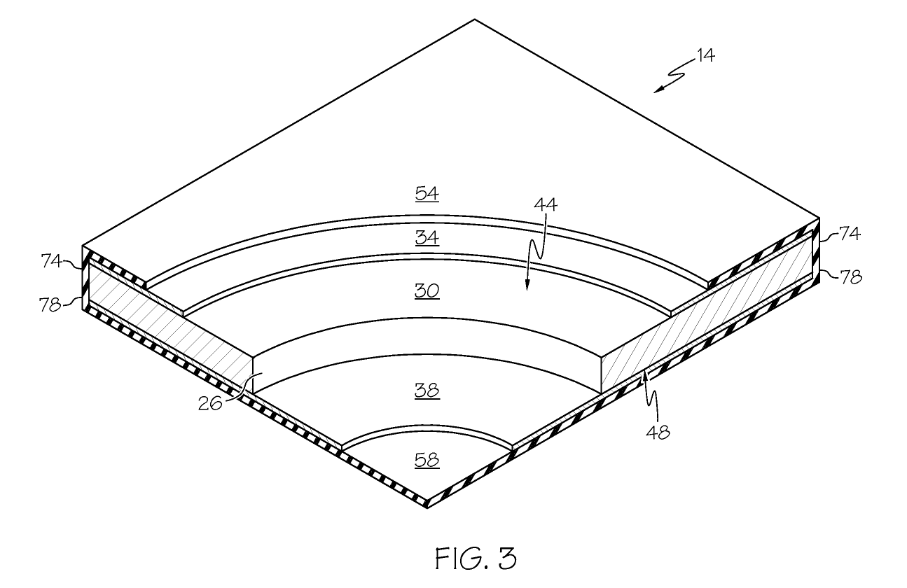

Referring to FIG. 3, the layered assembly 14 is shown in a flat position with portions of each layer removed for illustrative purposes. The thermoelectric material 30 that constitutes the core 26 can be made of solid composite materials as described in the paper, “Thermoelectric Behavior of Segregated-Network Polymer Nanocomposites,” James C. Grunlan, et al.; Nano Letters, 2008 Vol. 8, No. 12, pgs. 4428-4432, incorporated herein by reference in its entirety. Although this thermoelectric material includes both polymeric particles and carbon nano-particles, alternate thermoelectric materials may be employed as long as they meet the requirements outlined herein. The thermoelectric material 30 can be processed by methods, such as, casting or extruding, for example, to form a sheet of the core 26. After which, in this embodiment, the conductors 34, 38 are electrically and optionally mechanically bonded to the surfaces 44, 48 respectively. The conductors can be made of conductive materials, such as, copper, gold, silver or aluminum, for example. These materials can be bonded to the core 26 in one of several ways including, vapor deposition, soldering and brazing, for example. The insulative layers 54, 58 are bonded to the conductors 34, 38 respectively. The insulative layers 54, 48 may be sheets of insulative material such as polymeric, elastomeric or glass, for example. The insulative layers 54, 58 can be bonded to the conductors 34, 48 through chemical and mechanical means such as bonding with an adhesive agent, for example. Portions 74, 78 of the layers 54, 58 that extend beyond the core 26 and the conductors 34, 38 can be sealably attached to one another through adhesive means compatible with the material that the insulative layers 54, 58 are constructed of. In alternate embodiments the insulative layers 54, 58 can be applied to the core 26 and the conductors 34, 38 by conformal coating processes, such as, by dipping or spraying, for example.

The terminals 64, 68 can be electrically connected to the conductors 34, 38 either before or after the insulative layers 54, 48 are applied. Processes, such as, soldering, welding and brazing of the terminals 64, 68 to the conductors 34, 48 may be facilitated by doing so prior to application of the layers 54, 58 over the conductors 34, 38. Electrical attachment of the terminals 64, 68 to the conductors 34, 38 after the layers 54, 58 are applied can be done by insulation displacement methods. Regardless of the method of electrical attachment of the terminals 64, 68 to the conductors 34, 38 sealing of the terminals to the layers 54, 58 allows the layers 54, 58 to protect the conductors 34, 38 and the thermoelectric material 30 from fluids and other environmental conditions within which the layered assembly 14 may be submerged.

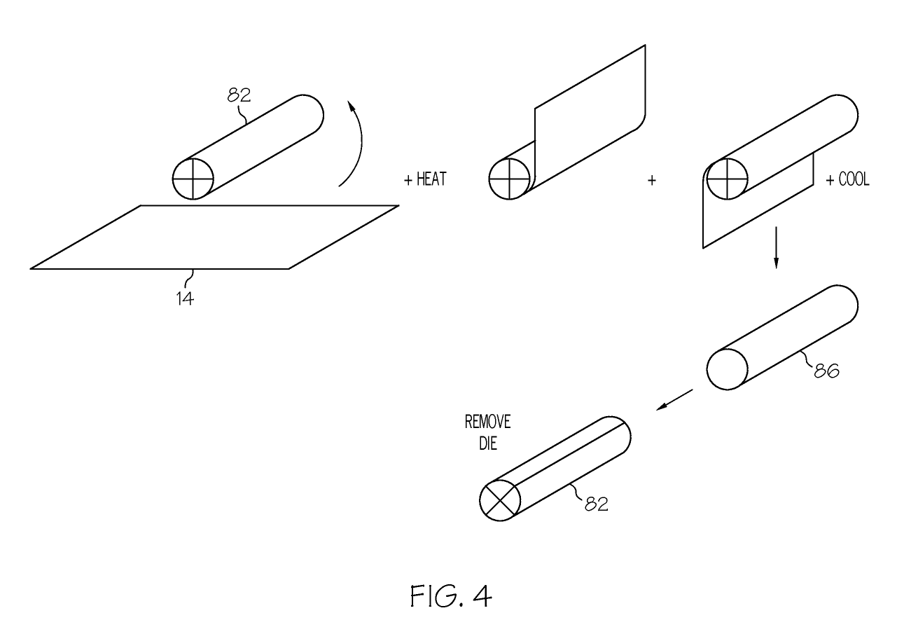

Referring to FIG. 4, the layered assembly 14 can be heated above a glass transition temperature of the materials employed and then rolled about a perimeter of a die 82 to a desired shape, such, as a cylinder 86, for example, as illustrated in this embodiment. After this forming operation, the layered assembly 14 can be cooled, to a temperature below the glass transition temperature, after which the die 82 may be removed therefrom. The formed layered assembly 14 can then be assembled about the tubular 22 and attached thereto by adhesive, clamping, or wrapping with another material, for example. Alternately, the layered assembly 14 can be formed directly onto the outer surface 18 of the tubular 22 thereby employing the tubular 22 as the die 82 in the forming process directly.

Since, as mentioned above, the thermoelectric material 30 may be extruded, as opposed to being cast, for example, it can be extruded directly into a desired shape, (i.e. the cylinder 86 in the example illustrated). Consequently, the shape of the core 26 of the thermoelectric material 30, as formed, can strongly influence which methods should be employed to bond the conductors 34, 38 and the insulative layers 54, 58 thereto. Regardless of the methods of assembly employed, however, the functioning of the finished power-generating device 10 should not be significantly altered.

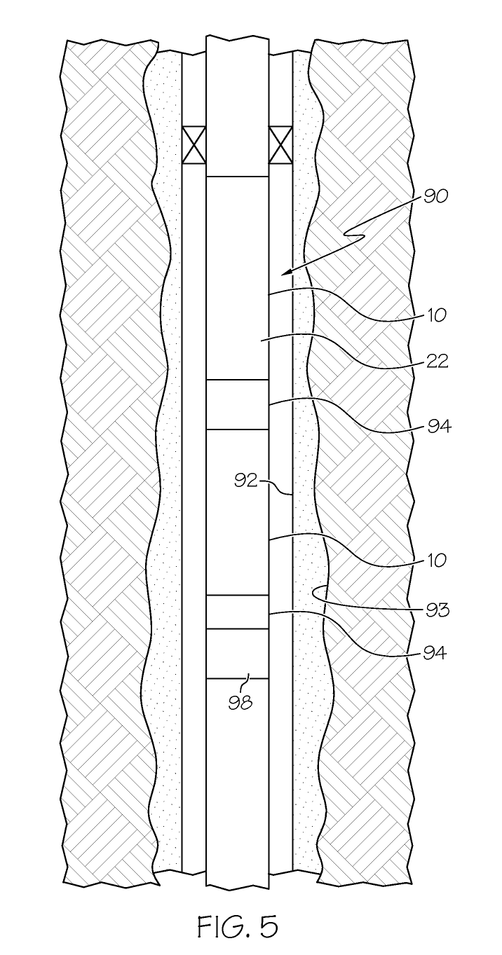

Referring to FIG. 5, although an embodiment of the power-generating device 10 disclosed herein is shown employed in a downhole completion application, it should be understood that the power-generating device 10 disclosed herein is not limited to such application. For example, the power-generating device 10 could be employed above ground on an oil or gas pipeline that have a temperature gradient thereacross. The downhole application illustrated herein shows two of the power-generating devices 10 positioned longitudinally displaced from one another along the tubular 22, illustrated herein as a drill or other type of string 90 positioned within a casing 92 in a borehole 93. The power-generating devices 10 are connected to one another through a connecting module 94 that provides electrical continuity from the terminals 64, 68 (not shown in this view) of one of the power-generating devices 10 to the terminals 64, 68 of the other of the power-generating devices 10. Although only two of the power-generating devices 10 are illustrated herein any number of the power-generating devices 10 could be connected in the same fashion. The connecting module 94 can connect two of the power-generating devices 10 along a single length of drill string pipe or can be configured to connect two of the power-generating devices 10 that are located on separate pipes of the string 90. The connecting module 94, or similar device, could connect power-generating devices 10 that are nested one radially inside of another. Additionally, the connecting module 94 of a similar device could also connect between one of the power-generating devices 10 and a tool 98, such as, an actuator, heater, motor, sensors, batteries or monitoring circuitry, for example, as illustrated. Since the surface area available along the string 90 for mounting a plurality of the power-generating devices 10 can be very large and the temperature differential across the power-generating devices 10 due to production fluids flowing therethrough can be significant the electrical energy generation potential is great. As such, the power-generating devices 10 disclosed herein can provide power to the tool 98 without having to be connected to surface nor having to generate the power downhole with movable componentry such as mud motors and turbines, for example.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed:

1. A power-generating device, comprising:
a thermoelectric material contoured to conform to at least a portion of a tubular; and
at least two conductors in operable communication with the thermoelectric material.

2. The power-generating device of claim 1, wherein the power-generating device is configured to be run into a borehole in a downhole completion application.

3. The power-generating device of claim 1, wherein the thermoelectric material is configured to generate electrical energy in response to a temperature gradient thereacross.

4. The power-generating device of claim 3, wherein the temperature gradient is oriented radially.

5. The power-generating device of claim 1, wherein the thermoelectric material is configured to perimetrically surround a tubular.

6. The power-generating device of claim 1, wherein the thermoelectric material has a shape of a curved sheet.

7. The power-generating device of claim 1, further comprising a protector in operable communication with the thermoelectric material.

8. The power-generating device of claim 7, wherein the protector is configured to seal the thermoelectric material from fluid within which the thermoelectric material and the protector are submerged.

9. The power-generating device of claim 7, wherein the protector is an electrical insulator.

10. The power-generating device of claim 1, wherein one of the at least two conductors is positioned radially inwardly of the thermoelectric material and another of the at least two conductors is positioned radially outwardly of the thermoelectric material.

11. The power-generating device of claim 1, wherein the at least two conductors are configured to transport electrical energy generated by the thermoelectric material.

12. The power-generating device of claim 1, wherein the thermoelectric material is formed by one of casting and extruding.

13. The power-generating device of claim 1, wherein the thermoelectric material is a solid composite material.

14. The power-generating device of claim 1, wherein the thermoelectric material includes both polymer particles and carbon nano-particles.

15. A method of making a generating device, comprising:
casting a sheet of thermoelectric material;
bonding a layer of conductive material to a first surface of the thermoelectric material;
bonding a layer of conductive material to a second surface of the thermoelectric material thereby constructing a layered assembly; and
forming the layered assembly to be perimetrically mountable to a tubular surface.

16. The method of making a generating device of claim 15, further comprising electrically insulating the conductive layers.

17. The method of making a generating device of claim 15, further comprising bonding the layered assembly to the tubular surface.

18. The method of making a generating device of claim 15, further comprising heating the layered assembly prior to the forming the layered assembly.

19. The method of making a generating device of claim 15, wherein the bonding the layers of conductive material includes electrically bonding.

20. A method of making a generating device, comprising:
extruding a thermoelectric material;
bonding a layer of conductive material to a first surface of the thermoelectric material;
bonding a layer of conductive material to a second surface of the thermoelectric material; and
forming the foregoing layered assembly to be perimetrically mountable to a tubular surface.

21. The method of making a generating device of claim 20, wherein the extruding the thermoelectric material includes extruding the thermoelectric material in a tubular shape.
